(19) United States
(12) Patent Application Publication
(10) Pub. No.: US 2024/0407269 A1
(43) Pub. Date: Dec. 5, 2024

(54) SPIN ORBIT TORQUE-BASED SWITCHING DEVICE USING CHIRAL STRUCTURE, AND METHOD FOR MANUFACTURING SAME

(71) Applicant: Daegu Gyeongbuk Institute of Science and Technology, Daegu (KR)

(72) Inventors: Chun Yeol YOU, Seoul (KR); Su Hyeok AN, Daegu (KR)

(73) Assignee: Daegu Gyeongbuk Institute of Science and Technology, Daegu (JP)

(21) Appl. No.: 18/698,511

(22) PCT Filed: Sep. 16, 2022
(86) PCT No.: PCT/KR2022/013869

§ 371 Date: Apr. 4, 2024

(30) Foreign Application Priority Data
Oct. 6, 2021 (KR) 10-2021-0132163

(51) Int. Cl. H10N 50/20; G11C 11/16; H10N 50/01; H10N 50/10; H10N 50/85

(52) U.S. Cl. CPC H10N 50/20; G11C 11/161; H10N 50/01; H10N 50/10; H10N 50/85

(57) ABSTRACT

The present invention pertains to: a switching device based on spin-orbit torque; and a method for manufacturing same. A switching device based on spin-orbit torque according to an embodiment comprises: a heavy metal input terminal extending in a first direction; and an information terminal extending in a second direction perpendicular to the first direction on the heavy metal input terminal and having a ferromagnetic layer, wherein the information terminal includes a first region adjacent to the heavy metal input terminal and a second region not adjacent to the heavy metal input terminal, and magnetization reversal of the ferromagnetic layer can be controlled on the basis of a non-uniform spin Hall effect (SHE) caused by the first region and the second region.

### TECHNICAL FIELD

The present disclosure relates to a spin orbit torque-based switching device and a method for manufacturing the same, and more particularly, to a technical idea of inputting information to a spin orbit torque-based switching device without an external magnetic field.

### BACKGROUND ART

In a spin orbit torque-based information storage medium, a current for inputting information thereto does not directly pass through a magnetic layer, unlike existing spin transfer torque-based technology. Thus, the spin orbit torque-based information storage medium has the advantage of allowing for more stable input due to less destruction of the magnetic layer due to the current. For this reason, research on information storage devices using the spin-orbit torque phenomenon has been actively conducted recently.

Currently ongoing spin-orbit torque-based device studies have many cases in which an input element has perpendicular magnetic anisotropy. In order to establish information input based on spin-orbit torque having the perpendicular magnetic anisotropy, application of a magnetic field in a plane direction is essential.

However, the application of the external magnetic field is the greatest disadvantage of the spin-orbit torque-based information input scheme. Thus, various technologies for performing information input using the spin-orbit torque without applying a planar magnetic field are proposed to overcome the problem. However, this technique requires an additional means for breaking magnetization symmetry inside a ferromagnetic layer.

### DISCLOSURE

### Technical Problem

A purpose of the present disclosure is to provide a spin orbit torque-based switching device capable of easily implementing a non-magnetic field magnetization reversal using only an input current applied through an input terminal without an external magnetic field application and without addition of an additional means for breaking magnetization symmetry, and a manufacturing method thereof.

Further, a purpose of the present disclosure is to provide a spin-orbit torque-based switching device capable of implementing a non-magnetic field magnetization reversal using a chiral spin structure inevitably generated in a ferromagnetic layer due to an input current, and a method for manufacturing the same.

### Technical Solution

A spin orbit torque-based switching device according to one embodiment of the present disclosure includes a heavy metal input terminal extending in a first direction; and an information terminal disposed on the heavy metal input terminal and extending in a second direction perpendicular to the first direction, wherein the information terminal includes a ferromagnetic layer, wherein the information terminal includes a first region adjacent to the heavy metal input terminal and a second region not adjacent to the heavy metal input terminal, wherein magnetization reversal of the ferromagnetic layer is controlled based on a non-uniform spin orbit torque effect (spin Hall effect: SHE) due to the first region and the second region.

According to one aspect, the magnetization reversal of the ferromagnetic layer of the information terminal is controlled based on the non-uniform spin orbit torque effect and a chiral spin structure generated in the ferromagnetic layer due to current applied to the information terminal through the heavy metal input terminal.

According to one aspect, a ratio of a width corresponding to the first direction to a length corresponding to the second direction is in a range of 1:2 to 1:9.

According to one aspect, the heavy metal input terminal includes at least one of platinum (Pt), tantalum (Ta), tungsten (W), hafnium (Hf), rhenium (Re), osmium (Os), iridium (Ir), and palladium (Pd).

According to one aspect, the ferromagnetic layer includes at least one of cobalt (Co), iron (Fe), nickel (Ni), boron (B), silicon (Si), zirconium (Zr), platinum (Pt), terbium (Tb), palladium (Pd), copper (Cu), tungsten (W), and tantalum (Ta).

According to one aspect, the information terminal further includes a tunnel barrier layer formed on the ferromagnetic layer.

According to one aspect, the tunnel barrier layer includes at least one of magnesium oxide (MgO), aluminum oxide (Al₂O₃), hafnium oxide (HfO₂), titanium oxide (TiO₂), yttrium oxide (Y₂O₃), and ytterbium oxide (Yb₂O₃).

According to one aspect, the device further includes a buffer layer formed under the heavy metal input terminal; and a protective layer formed on top of the information terminal.

A method for manufacturing a spin orbit torque-based switching device according to one embodiment of the present disclosure includes forming a heavy metal input terminal extending in a first direction; and forming an information terminal on the heavy metal input terminal, wherein the information terminal extends in a second direction perpendicular to the first direction and includes a ferromagnetic layer, wherein the information terminal includes a first region adjacent to the heavy metal input terminal and a second region not adjacent to the heavy metal input terminal, wherein magnetization reversal of the ferromagnetic layer is controlled based on a non-uniform spin orbit torque effect (spin Hall effect: SHE) due to the first region and the second region.

According to one aspect, the magnetization reversal of the ferromagnetic layer of the information terminal is controlled based on the non-uniform spin orbit torque effect and a chiral spin structure generated in the ferromagnetic layer due to current applied to the information terminal through the heavy metal input terminal.

According to one aspect, the forming of the information terminal includes forming the information terminal such that a ratio of a width of the information terminal corresponding to the first direction and a length of the information terminal corresponding to the second direction is in a range of 1:2 to 1:9.

### Technical Effect

According to an embodiment, the spin-orbit torque-based switching device of the present disclosure can easily implement the magnetic field magnetization reversal using only the input current applied through the input terminal without the application of the external magnetic field and without the addition of an additional means for breaking the magnetization symmetry.

Further, the spin-orbit torque-based switching device of the present disclosure can implement a non-magnetic field magnetization reversal using a chiral spin structure inevitably generated in a ferromagnetic layer due to an input current.

### BRIEF DESCRIPTION OF DRAWINGS

FIGS. 1A and 1B are diagrams for illustrating a spin-orbit torque-based switching device according to an embodiment.

FIG. 2 is a diagram for illustrating in more detail the spin-orbit torque-based switching device according to one embodiment.

FIG. 3 is a diagram for illustrating switching characteristics based on a magnetic field strength of the spin-orbit torque-based switching device according to one embodiment.

FIG. 4 is a diagram for illustrating a result of computational simulation of the switching characteristics of the spin-orbit torque-based switching device according to one embodiment.

FIG. 5 is a diagram for illustrating a manufacturing method of the spin-orbit torque-based switching device according to an embodiment.

FIGS. 6A to 6C are diagrams for illustrating in more detail the manufacturing method of the spin-orbit torque-based switching device according to one embodiment.

### BEST MODE

Hereinafter, various embodiments of the present disclosure will be described with reference to the accompanying drawings.

It should be understood that the embodiments and the terms used therein are not intended to limit the technological features set forth herein to particular embodiments and the present disclosure includes various changes of, equivalents, and/or replacements to the embodiment.

In the following description of various embodiments, when a detailed description of a related known function or configuration is determined to unnecessarily obscure the gist of the disclosure, the detailed description will be omitted.

The terms described below are terms defined in consideration of functions in various embodiments, and may vary depending on intention of the user or operator or custom. Therefore, the definition should be made based on the contents throughout this specification.

In relation to the description of the drawings, similar reference numerals may be used for similar components.

A singular expression may include a plural expression, unless the context clearly indicates otherwise.

In this document, expressions such as “A or B” or “at least one of A and/or B” may include all possible combinations of items listed together.

Expressions such as “first,” “second, etc. may modify corresponding components regardless of order or importance, and may be used only to distinguish one component from another component and does not limit the corresponding components.

When one (e.g., a first) component is “connected (functionally or communicatively)” or “linked” to another (e.g., second) component, this means that one component may be directly connected to another component or may be connected indirectly thereto via still another component (e.g., a third component).

As used herein, “configured to” may be used interchangeably with, for example, “adapted to”, “able to”, “modified to”, “designed to”, “suitable for”, “suitable for”, “capable of,” or “designed to” in hardware or software, depending on the context.

In some contexts, the expression “a device configured to” may mean that the device is “capable of” together with other devices or components.

For example, the phrase “processor configured to perform A, B, and C” may mean a dedicated processor (e.g. an embedded processor) for performing a corresponding operation, or a general-purpose processor (e.g. a CPU or an application processor) capable of performing corresponding operations by executing one or more software programs stored in a memory device.

Furthermore, the term ‘or’ means ‘inclusive or’ rather than ‘exclusive or’.

That is, unless otherwise stated or clear from the context, the expression ‘x uses a or b’ means one of natural inclusive permutations.

In the above-described specific embodiments, the components included in the present disclosure are expressed in the singular or plural according to the proposed specific embodiment.

However, the singular or plural expressions are selected to be suitable for the situation presented for convenience of description, and the above-described embodiments are not limited to the singular or plural components. Even when a component is expressed in a plural form, the component may be singular. Conversely, even when a component is expressed in a singular form, the component may include a plurality of components.

Further, the description of the disclosure are based on specific embodiments. However, various modifications are possible as long as they do not deviate from the scope of the technical idea implied by the various embodiments.

Therefore, the scope of the present disclosure should not be limited to the described embodiments, but should be determined based on the claims described below as well as equivalents to these claims.

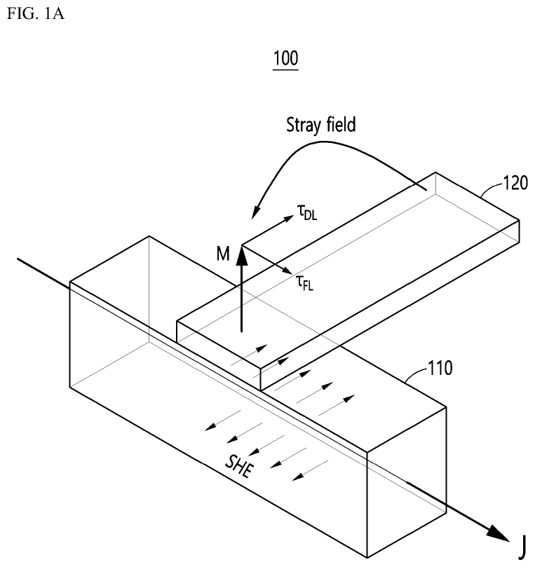

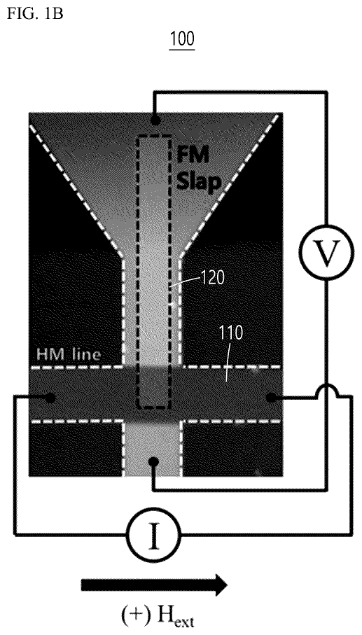

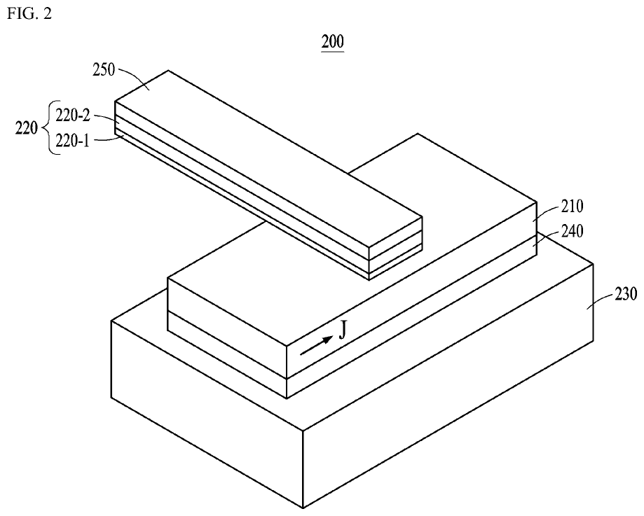

FIGS. 1A and 1B are diagrams for illustrating a spin-orbit torque-based switching device according to one embodiment.

Referring to FIGS. 1A and 1B, FIG. 1A illustrates a conceptual diagram of a spin orbit torque-based switching device according to an embodiment, and FIG. 1B illustrates an actual image of a spin orbit torque-based switching device according to an embodiment.

Specifically, the spin-orbit torque-based switching device 100 according to an embodiment may easily implement the magnetic-field magnetization reversal using only the input current applied through the input terminal without the application of the external magnetic field and without the addition of an additional means for breaking the magnetization symmetry.

Further, the spin-orbit torque-based switching device 100 may implement a non-magnetic-field magnetization reversal using a chiral spin structure inevitably generated in a ferromagnetic layer due to an input current.

To this end, the spin-orbit torque-based switching device 100 may include a heavy metal input terminal (HM line) 110 and an information terminal 120 formed on the heavy metal input terminal 110 and including a ferromagnetic layer (FM slap).

For example, the heavy metal input terminal 110 may include at least one of platinum (Pt), tantalum (Ta), tungsten (W), hafnium (Hf), rhenium (Re), osmium (Os), iridium (Ir), and palladium (Pd).

The ferromagnetic layer may include at least one of cobalt (Co), iron (Fe), nickel (Ni), boron (B), silicon (Si), zirconium (Zr), platinum (Pt), terbium (Tb), palladium (Pd), copper (Cu), tungsten (W), and tantalum (Ta).

Preferably, the heavy metal input terminal 110 may include a platinum (Pt) material, and the ferromagnetic layer may include a cobalt (Co) material.

Specifically, the heavy metal input terminal 110 may extend in a first direction, and the information terminal 120 may extend in a second direction perpendicular to the first direction and may be disposed on the heavy metal input terminal.

Further, the information terminal 120 may include a first region adjacent to the heavy metal input terminal 110 and a second region not adjacent to the heavy metal input terminal 110. The magnetization reversal of the ferromagnetic layer may be controlled based on a non-uniform spin orbit torque effect (SHE) due to the first region and the second region.

In other words, in the spin-orbit torque-based switching device 100, the heavy metal input terminal 110 for inputting information, and the information terminal 120 including the ferromagnetic layer having information corresponding to one of 0 and 1 may extend in an orthogonal manner to each other.

That is, unlike the conventional spin-orbit torque-based scheme, the information terminal 120 of the spin-orbit torque-based switching device 100 may not be positionally restricted to the heavy metal input terminal 110, but may be designed to have a sufficient length so as to be present beyond the heavy metal input terminal 110, and thus the magnetization reversal may be performed based on the non-uniform spin orbit torque effect and the chiral spin structure without applying an external magnetic field.

Preferably, the information terminal 120 may be formed such that a ratio (i.e. an aspect ratio) of a width corresponding toττ the first direction (i.e. the X-axis direction; τ_{FL} direction) and a length corresponding to the second direction (i.e. the Y-axis direction; τ_{DL} direction) may be optimized into a range of 1:2 to 1:9. For example, the information terminal 120 may have a ratio of the width and the length in a range of 1:8.3.

According to one aspect, the information terminal 120 may control the magnetization reversal of the ferromagnetic layer based on the non-uniform spin orbit torque effect and a chiral spin structure generated in the ferromagnetic layer due to current applied to the information terminal through the heavy metal input terminal 110.

For example, in the spin-orbit torque-based switching device 100, a separate current applying means may be connected to both opposing ends of the heavy metal input terminal 110, and a separate voltage applying means may be connected to both opposing ends of the ferromagnetic layer.

Further, in the spin-orbit torque-based switching device 100, the input current applied to the heavy metal input terminal 110 may be converted into a spin current by a spin Hall effect (SHE) inside the heavy metal input terminal 110. The converted spin current may apply a spin transfer effect to the magnetization of the ferromagnetic layer to perform the information input.

Specifically, when the spin orbit torque effect (SHE) is imparted to the magnetization of the ferromagnetic layer, the ferromagnetic layer designed in the optimized aspect ratio may be divided into a portion (i.e. the first region) affected by the spin orbit torque and a portion (i.e. the second region) that is not affected by the spin orbit torque to perform input of the information corresponding to 1 or 0 to the device based on the asymmetry between the two regions without the application of the external magnetic field.

More specifically, in the spin-orbit torque-based switching device 100, when the input current flows through the heavy metal input terminal 110, the spin current generated by the spin Hall effect affects the magnetization of the ferromagnetic layer (FM slap) provided in the information terminal 120. When a sufficient spin current flows in the ferromagnetic layer, the magnetization direction deviates from an axis along which the magnetization easily occurs due to the τDL and the τFL, and then is aligned with a direction in a plane.

In this case, in the spin-orbit torque-based switching device 100, the heavy metal input terminal 110 passes by only a portion of the ferromagnetic layer, such that the magnetization directions in the first region and the second region are different from each other, such that the chiral spin structure may be generated in the ferromagnetic layer. The thus-generated non-uniform magnetization structure may destroy the symmetry within the device by itself to implement the magnetization reversal without the application of the external magnetic field.

The spin orbit torque-based switching device according to an embodiment will be described in more detail with reference to FIG. 2.

FIG. 2 is a diagram for more specifically illustrating the spin orbit torque-based switching device according to one embodiment.

Referring to FIG. 2, a spin orbit torque-based switching device 200 may include a heavy metal input terminal 210 extending in the first direction and an information terminal 220 extending in the second direction perpendicular to the first direction and disposed on the heavy metal input terminal 210.

In one aspect, the information terminal 220 may include a ferromagnetic layer 220-1 and a tunnel barrier layer 220-2 formed on the ferromagnetic layer 220-1.

Further, the information terminal 220 may include a first region adjacent to the heavy metal input terminal 210 and a second region not adjacent to the heavy metal input terminal 210. The magnetization reversal of the ferromagnetic layer 220-1 may be controlled based on the non-uniform spin orbit torque effect (SHE) due to the first region and the second region.

For example, the heavy metal input terminal 110 may include at least one of platinum (Pt), tantalum (Ta), tungsten (W), hafnium (Hf), rhenium (Re), osmium (Os), iridium (Ir), and palladium (Pd).

Further, the heavy metal input terminal 110 preferably has a very small thickness, and specifically has a thickness of 0.1 nm to 3 nm. This is because when the heavy metal layer 110 has a significantly small thickness in a range of 0.1 nm to 3 nm, skyrmion nucleation may occur at an interface thereof with the ferromagnetic layer 220-1.

The ferromagnetic layer 220-1 may include at least one of cobalt (Co), iron (Fe), nickel (Ni), boron (B), silicon (Si), zirconium (Zr), platinum (Pt), terbium (Tb), palladium (Pd), copper (Cu), tungsten (W), and tantalum (Ta).

The tunnel barrier layer 220-2 may include at least one of magnesium oxide (MgO), aluminum oxide (Al₂O₃), hafnium oxide (HfO₂), titanium oxide (TiO₂), yttrium oxide (Y₂O₃), and ytterbium oxide (Yb₂O₃). Preferably, the tunnel barrier layer 220-2 may include a magnesium oxide (MgO) material.

Further, the heavy metal input terminal 210 may include a platinum (Pt) material, and the ferromagnetic layer 220-1 may include a cobalt (Co) material.

The spin-orbit torque-based swivel element 200 may be formed on a semiconductor substrate 230 including at least one of doped or undoped silicon (Si), other semiconductor materials other than silicon such as germanium, a compound semiconductor including silicon carbide, gallium arsenic, gallium phosphide, gallium nitride, indium phosphide, indium arsenide, and/or indium antimonide, or an alloy semiconductor including silicon germanium (SiGe), GaAsP, AlInAs, AlGaAs, GalnAs, GalnP, and GaInAsP.

Preferably, the spin-orbit torque-based switching device 200 may be formed on a silicon oxide (SiO₂) layer whose a cross section is subjected to a planarization process of the silicon (Si) substrate 230, using a magnetron sputter.

Further, the spin orbit torque-based switching device 200 may further include a buffer layer 240 formed under the heavy metal input terminal and a protective layer 250 formed on top of the information terminal 220.

For example, each of the buffer layer 240 and the protective layer 250 may include at least one of a non-magnetic metal material such as tantalum (Ta), chromium (Cr), ruthenium (Ru), a non-magnetic compound such as cobalt gallium (CoGa) and manganese gallium nitride (MnGaN), and a non-magnetic alloy such as nickel aluminum (NiAl). Preferably, each of the buffer layer 240 and the protective layer 250 may include a tantalum (Ta) material.

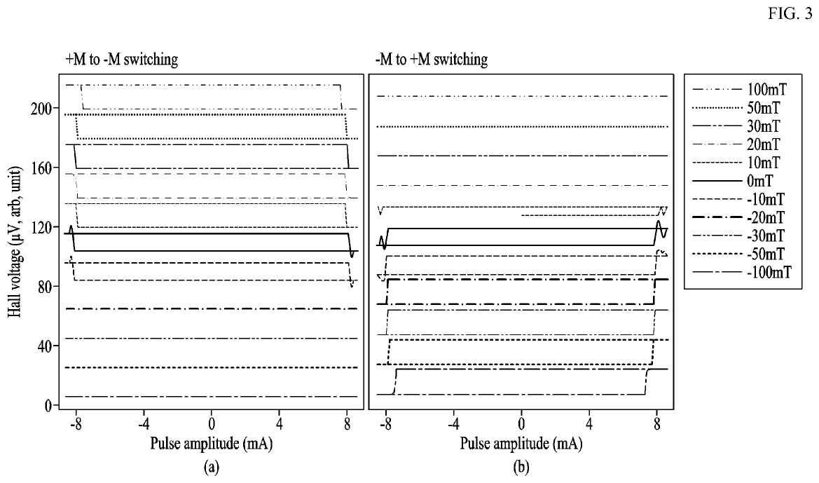

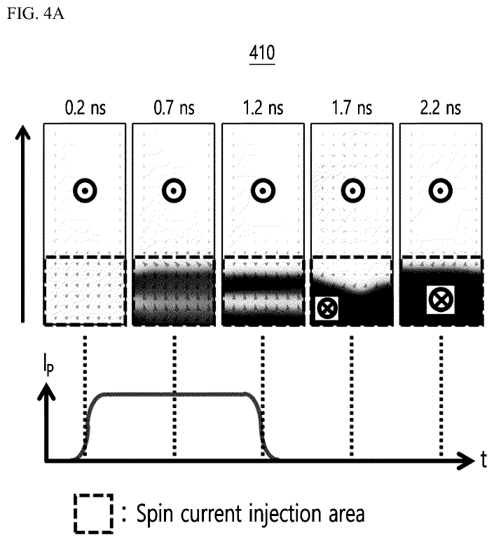

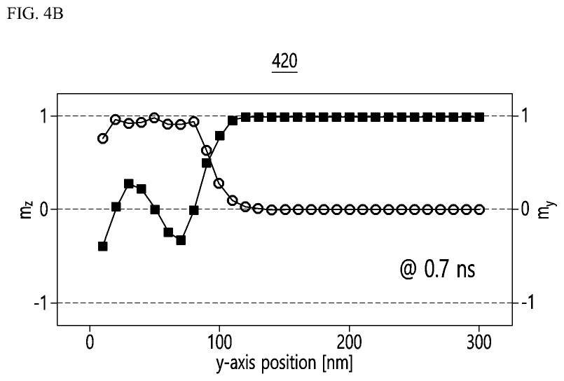

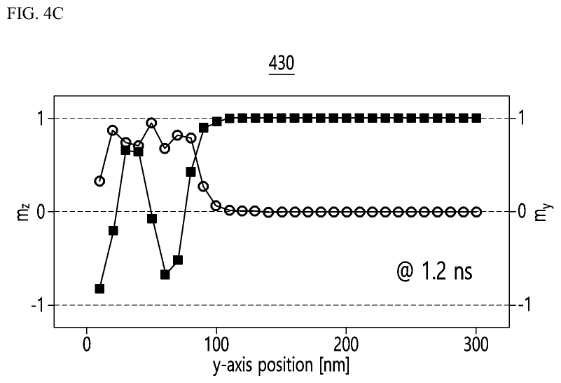

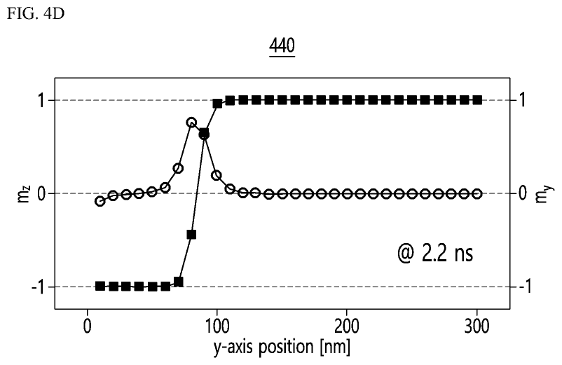

FIG. 3 is a diagram for illustrating a switching characteristic based on a magnetic field strength of the spin orbit torque-based switching device according to an embodiment, and FIGS. 4A to 4D are diagrams for illustrating a computational simulation result on switching characteristics of the spin orbit torque-based switching device according to an embodiment.

Referring to FIGS. 3 to 4D, (a) in FIG. 3 shows a switching result of the spin-orbit torque-based switching device according to an embodiment when a magnetic field of −100 mT to 100 mT is applied thereto in a +M to −M direction. (b) in FIG. 3 shows a switching result of the spin-orbit torque-based switching device according to an embodiment when a magnetic field of −100 mT to 100 mT is applied thereto in a −M to +M direction (that is, in a direction opposite to the application direction of (a) in FIG. 3).

Further, a reference numeral 410 shows a result of analyzing a switching result of the spin orbit torque-based switching device according to an embodiment using micromagnetic computational simulation. Reference numerals 420, 430, and 440 respectively show changes in moments (specifically, a moment my in the y-axis direction, m_{z} in the z-axis direction) at times t=0.7 ns, t=1.2 ns, and t=2.2 ns which are derived through the micromagnetic computational simulation.

Specifically, in the spin orbit torque-based switching device according to an embodiment, the heavy metal input terminal and the information terminal including the ferromagnetic layer are perpendicular to each other, and the information terminal of the spin-orbit torque-based switching device may not be positionally restricted to the heavy metal input terminal, but may be designed to have a sufficient length so as to be present beyond the heavy metal input terminal, and thus, the magnetization reversal may be performed based on the non-uniform spin orbit torque effect and the chiral spin structure without applying an external magnetic field.

Specifically, in the spin-orbit torque-based switching device according to an embodiment, when the spin orbit torque effect (SHE) is imparted to the magnetization of the ferromagnetic layer, the ferromagnetic layer designed in the optimized aspect ratio may be divided into a portion (i.e. the first region) affected by the spin orbit torque and a portion (i.e. the second region) that is not affected by the spin orbit torque to perform input of the information corresponding to 1 or 0 to the device based on the asymmetry between the two regions without the application of the external magnetic field.

Referring to (a) and (b) in FIG. 3, when the magnetization reversal using the spin orbit torque was observed in the spin-orbit torque-based switching device according to an embodiment, it was identified that the magnetization reversal occurred when the external magnetic field is not at 0 mT but at about 100 mT, which means that sufficient asymmetry had been formed in the sample.

Specifically, referring to (a) and (b) in FIG. 3, based on a result of observing the spin-orbit torque-induced magnetization reversal according to the magnetization direction, in the spin-orbit torque-based switching device according to an embodiment, the asymmetry depends only on the direction of the initial magnetization because the direction of the current and the direction of the magnetic field when the measurement is performed are fixed. This proves that the direction of the internal asymmetry is reversed by the magnetization reversal, and this means the internal spin structure asymmetry affects the spin orbit torque induced magnetization reversal.

That is, the spin orbit torque-based switching device according to an embodiment can achieve the magnetization reversal without the external magnetic field when the spin orbit torque affects only a partial region of the ferromagnetic layer. This may be identified through the computational simulation result shown in the reference numeral 410.

The reference numerals 420 to 440 suggest that the spatial spin structure has non-uniformity and chirality at each of the times (t=0.7 ns, t=1.2 ns and t=2.2 ns). In other words, it was identified through the computational simulation that a spatial chiral spin structure is actually formed due to the non-uniform spin orbit effect.

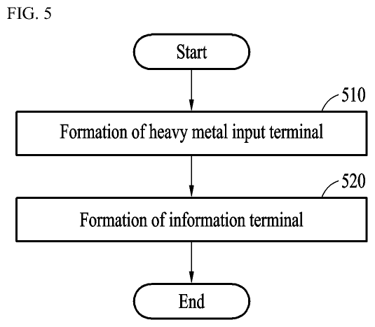

FIG. 5 is a diagram for illustrating a method for manufacturing a spin orbit torque-based switching device according to an embodiment.

Referring to FIG. 5, in operation 510, a method for manufacturing the spin orbit torque-based switching device may include forming the heavy metal input terminal extending in the first direction.

For example, the heavy metal input terminal may include at least one of platinum (Pt), tantalum (Ta), tungsten (W), hafnium (Hf), rhenium (Re), osmium (Os), iridium (Ir), and palladium (Pd).

Next, in operation 520, the method for manufacturing the spin-orbit torque-based switching device may include forming the information terminal including the ferromagnetic layer and extending in the second direction perpendicular to the first direction on the heavy metal input terminal.

For example, the ferromagnetic layer may include at least one of cobalt (Co), iron (Fe), nickel (Ni), boron (B), silicon (Si), zirconium (Zr), platinum (Pt), terbium (Tb), palladium (Pd), copper (Cu), tungsten (W), and tantalum (Ta).

The information terminal may include the first region adjacent to the heavy metal input terminal and the second region not adjacent to the heavy metal input terminal. Thus, the magnetization reversal of the ferromagnetic layer may be controlled based on the non-uniform spin orbit torque effect (SHE) due to the first region and the second region.

Specifically, the magnetization reversal of the ferromagnetic layer of the information terminal may be controlled based on the non-uniform spin orbit torque effect and the chiral spin structure generated in the ferromagnetic layer due to the current applied to the information terminal through the heavy metal input terminal.

According to an aspect, in operation 520, the method for manufacturing the spin-orbit torque-based switching device may include forming the information terminal such that the ratio of the width of the information terminal corresponding to the first direction and the length of the information terminal corresponding to the second direction is in a range of 1:2 to 1:9.

For example, in operation 520, the method for manufacturing the spin-orbit torque-based switching device may include forming the information terminal having a width of 1.2 μm and a length of 10 μm.

In operation 520, the method for manufacturing the spin-orbit torque-based switching device may include forming the ferromagnetic layer disposed on the heavy metal input terminal and extending in the second direction perpendicular to the first direction, and forming the tunnel barrier layer on the ferromagnetic layer.

For example, the tunnel barrier layer may include at least one of magnesium oxide (MgO), aluminum oxide (Al₂O₃), hafnium oxide (HfO₂), titanium oxide (TiO₂), yttrium oxide (Y₂O₃), and ytterbium oxide (Yb₂O₃).

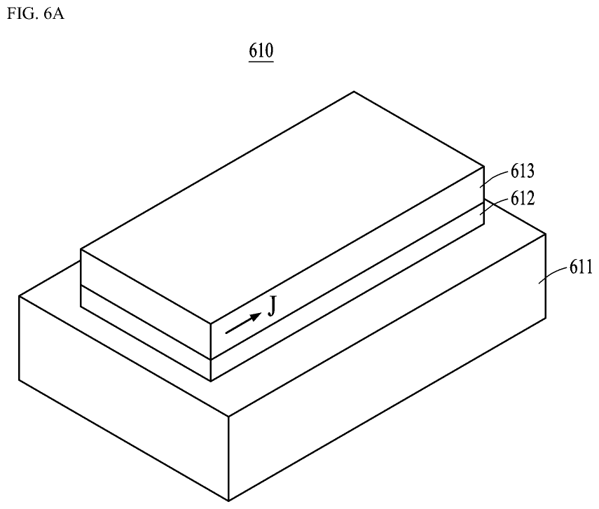

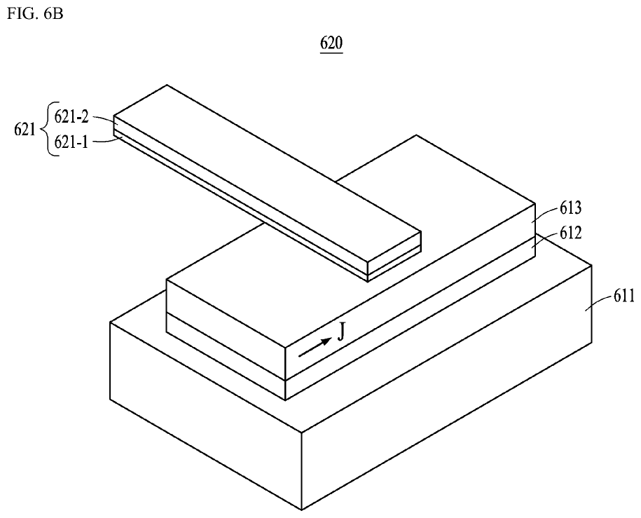

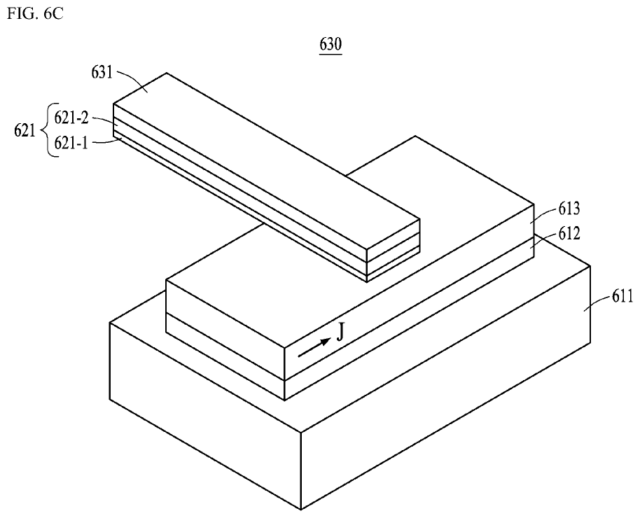

The method for manufacturing the spin orbit torque-based switching device according to an embodiment will be described in more detail with reference to FIGS. 6A to 6C.

FIGS. 6A to 6C are views for more specifically illustrating the method for manufacturing the spin orbit torque-based switching device according to an embodiment.

Referring to FIGS. 6A to 6C, the spin-orbit torque-based switching device according to an embodiment as described below may be formed on a semiconductor substrate 611 including at least one of doped or undoped silicon (Si), other semiconductor materials other than silicon such as germanium, a compound semiconductor including silicon carbide, gallium arsenic, gallium phosphide, gallium nitride, indium phosphide, indium arsenide, and/or indium antimonide, or an alloy semiconductor including silicon germanium (SiGe), GaAsP, AlInAs, AlGaAs, GaInAs, GalnP, and GaInAsP.

Preferably, the spin-orbit torque-based switching device according to an embodiment may be formed on a silicon oxide (SiO₂) layer whose a cross section is subjected to a planarization process of the silicon (Si) substrate 611, using a magnetron sputter.

Specifically, in operation 610, the method for manufacturing the spin-orbit torque-based switching device may include forming the buffer layer 612 extending in the first direction on the silicon oxide layer (SiO₂) 611, and forming a heavy metal input terminal 613 extending in the first direction on the buffer layer 612.

For example, the buffer layer 612 may be embodied as a tantalum (Ta) layer having a thickness of 3 nm, and the heavy metal input terminal 613 may be embodied as a platinum (Pt) layer having a thickness of 5 nm.

Next, in operation 620, the method for manufacturing the spin-orbit torque-based switching device may include forming the information terminal 621 extending in a second direction perpendicular to the first direction on the heavy metal input terminal.

More specifically, in operation 620, the method for manufacturing the spin-orbit torque-based switching device may include forming a ferromagnetic layer 621-1 extending in the second direction on the heavy metal input terminal, and forming a tunnel barrier layer 621-2 extending in the second direction on the ferromagnetic layer 621-1.

For example, the ferromagnetic layer 621-1 may be embodied as a cobalt (Co) layer having a thickness of 0.8 nm, and the tunnel barrier layer 621-2 may be embodied as a magnesium oxide layer having a thickness of 2 nm. Further, the ferromagnetic layer 621-1 may have a width of 1.2 μm and a length of 10 μm.

Next, in operation 630, the method for manufacturing the spin-orbit torque-based switching device may include forming a protective layer 631 extending in the second direction on the tunnel barrier layer 621-2. For example, the protective layer 631 may be embodied as a tantalum (Ta) layer having a thickness of 2 nm.

That is, the spin orbit torque-based switching device according to an embodiment may include a stack structure of the heavy metal input terminal 613/ferromagnetic layer 621-1/tunnel barrier layer 621-2, and the buffer layer 612 and the protective layer 631 respectively disposed under and on top of the stack structure to secure/preserve perpendicular magnetic anisotropy.

In one example, the method for manufacturing the spin orbit torque-based switching device according to an embodiment may include performing two argon (Ar) ion milling dry etching processes to complete the switching device.

In this regard, a first etching process may be an entire layer etching process for forming a current line through which electricity flows, that is, the heavy metal input terminal 613, while a second etching process may be a selective layer etching process for forming a ferromagnetic slab, that is, the ferromagnetic layer 621-1.

Specifically, in the etching process according to an embodiment, the argon gas flowing in the milling gun may be ionized by using thermal electrons emitted from the tungsten wire, and the ionized argon ions may be accelerated with 400 V to 600 V so as to collide with the surface of the sample, thereby etching the material. A resist pattern may be formed on the surface of the sample using an electron beam or photolithography so that a portion to be etched and a portion to be etched are not etched are distinguished from each other.

For example, for the uniform surface etching of the sample, the sample may rotate at 20 rpm while being tilted by 5° relative to the ion incidence during the etching process.

More specifically, the method for manufacturing the spin orbit torque-based switching device according to an embodiment may include patterning a first resist pattern corresponding to a current line, that is, the heavy metal input terminal, on a thin film sample including a heavy metal material/ferromagnetic material/oxide using lithography, and etching all layers. In this case, when the buffer layer or the protective layer is present, the first etching process may be performed thereon.

Next, the method for manufacturing the spin-orbit torque-based switching device according to the embodiment may include removing the first resist pattern after the first etching process is completed.

Next, the method for manufacturing the spin-orbit torque-based switching device according to the embodiment may include patterning a second resist pattern corresponding to the ferromagnetic slab on the sample subjected to the first etching process in the same manner as in the first etching process, and then, performing a second etching process thereon. In this regard, the etching may be stopped before the heavy metal input terminal is etched. In the pattern excluding the ferromagnetic slab, the heavy metal input terminal may be exposed.

Next, the method for manufacturing the spin-orbit torque-based switching device according to the embodiment may include removing the second resist pattern after the second etching process is completed.

According to an embodiment, the method for manufacturing the spin-orbit torque-based switching device may calculate a ratio of an etching time of each material to etch each layer, and may estimate a total etching time based on the calculated ratio to perform the above-described etching process.

Further, the method for manufacturing the spin orbit torque-based switching device according to an embodiment may include estimating, by a user, a thickness of the etched sample through a transparent substrate to perform the above-described etching process.

In one example, in the method for manufacturing the spin-orbit torque-based switching device according to an embodiment, after the etching process is finished, a gold (Au) or copper (Cu) electrode may be deposited thereon to complete the switching device.

As a result, according to the present disclosure, the non-magnetic spin orbit torque-based information input scheme to the ferromagnetic layer occupying only a portion of the heavy metal input terminal may be used to form the conventional spin-orbit torque-based memory device. Further, the information input may be freely performed only using the current via the input terminal element such as a magnetic domain wall-based spin torque majority gate in which the information input terminal includes information transfer without the external magnetic field, and the switching device may be easily formed compared to an existing technology.

Further, the present disclosure may be used not only in the conventional spin-orbit torque-based memory device, but also in the magnetic domain wall-based spin torque majority gate.

Although the embodiments have been described above with reference to the drawings, various modifications and variations may be made by one of ordinary skill in the art. For example, appropriate results may be achieved even when the described techniques may be performed in a different order than the described order, and/or components of systems, structures, apparatuses, circuits, etc. as described may be combined with each other in a different form than the described form, or may be replaced or substituted with other components or equivalents.

Therefore, other implementations, other embodiments, and equivalent to the claims belong to the scope of the following claims.

1. A spin orbit torque-based switching device comprising:
a heavy metal input terminal extending in a first direction; and
an information terminal disposed on the heavy metal input terminal and extending in a second direction perpendicular to the first direction, wherein the information terminal includes a ferromagnetic layer,
wherein the information terminal includes a first region adjacent to the heavy metal input terminal and a second region not adjacent to the heavy metal input terminal,
wherein magnetization reversal of the ferromagnetic layer is controlled based on a non-uniform spin orbit torque effect (spin Hall effect: SHE) due to the first region and the second region.

2. The spin orbit torque-based switching device of claim 1, wherein the magnetization reversal of the ferromagnetic layer of the information terminal is controlled based on the non-uniform spin orbit torque effect and a chiral spin structure generated in the ferromagnetic layer due to current applied to the information terminal through the heavy metal input terminal.

3. The spin orbit torque-based switching device of claim 1, wherein a ratio of a width corresponding to the first direction to a length corresponding to the second direction is in a range of 1:2 to 1:9.

4. The switching device of claim 1, wherein the heavy metal input terminal includes at least one of platinum (Pt), tantalum (Ta), tungsten (W), hafnium (Hf), rhenium (Re), osmium (Os), iridium (Ir), and palladium (Pd).

5. The spin orbit torque-based switching device of claim 1, wherein the ferromagnetic layer includes at least one of cobalt (Co), iron (Fe), nickel (Ni), boron (B), silicon (Si), zirconium (Zr), platinum (Pt), terbium (Tb), palladium (Pd), copper (Cu), tungsten (W), and tantalum (Ta).

6. The spin orbit torque-based switching device of claim 1, wherein the information terminal further includes a tunnel barrier layer formed on the ferromagnetic layer.

7. The spin orbit torque-based switching device of claim 6, wherein the tunnel barrier layer includes at least one of magnesium oxide (MgO), aluminum oxide (Al₂O₃), hafnium oxide (HfO₂), titanium oxide (TiO₂), yttrium oxide (Y₂O₃), and ytterbium oxide (Yb₂O₃).

8. The spin orbit torque-based switching device of claim 1, further comprising:
a buffer layer formed under the heavy metal input terminal; and
a protective layer formed on top of the information terminal.

9. A method for manufacturing a spin orbit torque-based switching device, the method comprising:
forming a heavy metal input terminal extending in a first direction; and
forming an information terminal on the heavy metal input terminal, wherein the information terminal extends in a second direction perpendicular to the first direction and includes a ferromagnetic layer,
wherein the information terminal includes a first region adjacent to the heavy metal input terminal and a second region not adjacent to the heavy metal input terminal,
wherein magnetization reversal of the ferromagnetic layer is controlled based on a non-uniform spin orbit torque effect (spin Hall effect:SHE) due to the first region and the second region.

10. The method for manufacturing the spin orbit torque-based switching device of claim 9, wherein the magnetization reversal of the ferromagnetic layer of the information terminal is controlled based on the non-uniform spin orbit torque effect and a chiral spin structure generated in the ferromagnetic layer due to current applied to the information terminal through the heavy metal input terminal.

11. The method for manufacturing the spin orbit torque-based switching device of claim 9, wherein the forming of the information terminal includes forming the information terminal such that a ratio of a width of the information terminal corresponding to the first direction and a length of the information terminal corresponding to the second direction is in a range of 1:2 to 1:9.
